(19) United States
(12) Patent Application Publication
(10) Pub. No.: US 2024/0128062 A1
(43) Pub. Date: Apr. 18, 2024

(54) MONOLITHIC ANISOTROPIC SUBSTRATE SUPPORTS

(71) Applicant: LAM RESEARCH CORPORATION, Fremont, CA (US)

(72) Inventors: Joel HOLLINGSWORTH, Portland, OR (US); Ramkishan LINGAMPALLI, Danville, CA (US); Karl LEESER, West Linn, OR (US); Stephen TOPPING, Portland, OR (US); Noah Elliot BAKER, West Linn, OR (US)

(21) Appl. No.: 17/769,430

(22) PCT Filed: Oct. 20, 2020
(86) PCT No.: PCT/US2020/056436

§ 371 Date: Apr. 15, 2022

Related U.S. Application Data
(60) Provisional application No. 62/923,912, filed on Oct. 21, 2019.

(51) Int. Cl. H01J 37/32; C23C 16/458

(52) U.S. Cl. CPC H01J 37/32724; C23C 16/4581; C23C 16/4586; H01J 37/32568; H01J 37/32807; H01J 2237/2007; H01J 2237/3321

(57) ABSTRACT

A substrate support includes a monolithic anisotropic body, which includes first, second and intermediate layers. The first layer is formed of a first material and disposed therein are RF and clamping electrodes. The second layer is formed of the first material or a second material and disposed therein is a heating element. The intermediate layer is formed of a different material than the first and second layers, such that at least one of: a thermal energy conductivity of the intermediate layer is different than a thermal energy conductivity of at least one of the first or second materials; or an electrical energy conductivity of the intermediate layer is different than an electrical conductivity of at least one of the first or second materials. Either the intermediate layer is disposed between the first and second layers or the second layer is disposed between the first and intermediate layers.

### CROSS-REFERENCE TO RELATED APPLICATIONS

This application claims the benefit of U.S. Provisional Application No. 62/923,912, filed on Oct. 21, 2019. The entire disclosure of the application referenced above is incorporated herein by reference.

### FIELD

The present disclosure relates to electrostatic chucks of substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A monolithic substrate support (e.g., a monolithic pedestal or electrostatic chuck) may include a bulk ceramic body. Electrostatic clamping and radio frequency (RF) electrodes and one or more heater elements are disposed in the bulk ceramic body. The monolithic substrate support can experience local hot spots that shift kinetics of processes performed on substrates. Two causes of hot spots are insufficient spreading of thermal energy and non-reproducible placement of heater elements within a ceramic body.

Thick ceramic bodies are typically better able to spread thermal energy more evenly than thin ceramic bodies. However, increasing thickness of a ceramic body increases the amount of material used, which increases material and manufacturing costs. Increased thickness can also negatively affect placement reproducibility of internal components (e.g., electrodes and heating elements) and thus negatively affect throughput in manufacturing of substrate supports. For example, raw material powder can shift during manufacturing, which shifts placement of internal components. The amount of shifting and/or the probability of shifting occurring increase the thicker the ceramic body. Also, ceramic substrate supports are vulnerable to mechanical failure due to thermal stress.

### SUMMARY

A substrate support is provided and includes a radio frequency electrode, a clamping electrode, a heating element, and a monolithic anisotropic body. The monolithic anisotropic body includes a first layer, a second layer and a first intermediate layer. The first layer is formed of a first material and disposed therein are the radio frequency electrode and the clamping electrode. The second layer is formed of the first material or a second material and disposed therein is the heating element. The first intermediate layer is formed of a different material than the first layer and the second layer, such that at least one of: a thermal energy conductivity of the first intermediate layer is different than a thermal energy conductivity of at least one of the first material or the second material; or an electrical energy conductivity of the first intermediate layer is different than an electrical conductivity of at least one of the first material or the second material. Either the first intermediate layer is disposed between the first layer and the second layer or the second layer is disposed between the first layer and the first intermediate layer.

In other features, the first intermediate layer is formed of a different material than the first layer and the second layer, such that: the thermal energy conductivity of the first intermediate layer is different than the thermal energy conductivity of at least one of the first material or the second material; and the electrical energy conductivity of the first intermediate layer is different than the electrical conductivity of at least one of the first material or the second material.

In other features, the first intermediate layer is formed of a different material than the first layer and the second layer, such that at least one of: the thermal energy conductivity of the first intermediate layer is different than the thermal energy conductivity of the first material and the second material; or the electrical energy conductivity of the first intermediate layer is different than the electrical conductivity of the first material and the second material.

In other features, a coefficient of thermal expansion of the first intermediate layer is different than a coefficient of thermal expansion of at least one of the first material or the second material.

In other features, the first intermediate layer includes an inner portion and an outer portion. The inner portion is formed of a different material than the first layer and the second layer. The outer portion is formed of the first material or the second material.

In other features, the substrate support further includes a metal layer disposed between the first intermediate layer and the second layer. In other features, the metal layer is implemented as a metal screen or metal mesh.

In other features, the second layer is formed of the first material. In other features, the first intermediate layer includes: an inner portion encased in a coating layer; and an outer portion surrounding the inner portion.

In other features, the first intermediate layer includes a solid structure having at least one of a different density, porosity per unit area or number of cracks per unit area than the first layer, the second layer and the first intermediate layer of the monolithic anisotropic body.

In other features, the first intermediate layer includes a solid structure consolidated prior to consolidation of the first layer, the second layer and the first intermediate layer to form the monolithic anisotropic body.

In other features, the substrate support further includes a second intermediate layer disposed below the second layer and formed of a different material than the first layer and the second layer, such that at least one of: a thermal energy conductivity of the second intermediate layer is different than the thermal energy conductivity of at least one of the first material or the second material; or an electrical energy conductivity of the second intermediate layer is different than the electrical conductivity of at least one of the first material or the second material.

In other features, the second intermediate layer includes an inner portion and an outer portion. The inner portion is formed of a different material than the first layer and the second layer. The outer portion is formed of the first material or the second material.

In other features, the substrate support further includes: a first metal layer disposed between the first intermediate layer and the second layer; and a second metal layer disposed between the second layers and the second intermediate layer.

In other features, the first intermediate layer includes: a first inner portion encased in a first coating layer; and a first outer portion surrounding the first inner portion. The second intermediate layer includes: a second inner portion encased in a second coating layer; and a second outer portion surrounding the second inner portion.

In other features, the first intermediate layer includes a first solid structure and the second intermediate layer includes a second solid structure. The first solid structure and the second solid structure have at least one of a different density, porosity per unit area or number of cracks per unit area than the first layer, the second layer, a remainder of the first intermediate layer and a remainder of the second intermediate layer of the monolithic anisotropic body.

In other features, the first intermediate layer includes a first solid structure and the second intermediate layer includes a second solid structure, which were consolidated prior to consolidation of the first layer, the second layer, the first intermediate layer and the second intermediate layer to form the monolithic anisotropic body.

In other features, the monolithic anisotropic body includes a hollow interior area shaped similarly as the heating element and constraining the heating element. In other features, the monolithic anisotropic body includes fasteners for limiting movement of the heating element relative to the monolithic anisotropic body. In other features, the first intermediate layer comprises at least one of a ring or a void.

In other features, the first intermediate layer includes a void filled with an insulating gas or a conductive fluid. In other features, the monolithic anisotropic body includes vertically extending beams. The beams are formed of a different material than the first layer and the second layer.

In other features, a method of forming a substrate support is provided. The method includes: arranging first material and a first object within a first die to create an initial pre-form; sintering the initial pre-form to provide a first initial internal structure; arranging the first initial internal structure, second material, and a second object within a second die to create a final pre-form; and sintering the final pre-form to provide the substrate support. The first object and the second object include a heating element, a clamping electrode and a radio frequency electrode.

In other features, the method further includes applying pressure on the initial pre-form at least one of prior to or while sintering the initial pre-form. In other features, the method further includes refraining from applying pressure on the initial pre-form at least one of prior to or while sintering the initial pre-form. In other features, the method further includes applying pressure on the final pre-form at least one of prior to or while sintering the final pre-form.

In other features, the method further includes refraining from applying pressure on the final pre-form at least one of prior to or while sintering the final pre-form. In other features, the method further includes forming internal structures including the initial internal structure. The creating of the final pre-form includes arranging the internal structures in the second die.

In other features, the method further includes: collecting and arranging the first initial internal structure and at least one of third material or a third object in a third die to form an intermediate pre-form; and sintering the intermediate pre-form to form an intermediate internal structure. The creating of the final pre-form includes arranging the intermediate internal structure in the second die.

In other features, the method further includes machining the initial internal structure prior to creating the final pre-form and arranging the initial internal structure in the second die. In other features, the substrate support has a green sheet structure. In other features, the creating of the initial preform includes forming a stack of layers.

In other features, a substrate support is provided and includes a radio frequency electrode, a clamping electrode, a heating element, and a monolithic anisotropic body. The monolithic anisotropic body includes: a first one or more layers formed of a first material and including the radio frequency electrode and the clamping electrode; a second one or more layers formed of the first material or a second material and including the heating element; and a first intermediate layer. The first intermediate layer is disposed between the first one or more layers and the second one or more layers and formed of a different material than the first one or more layers and the second one or more layers, such that at least one of: a thermal energy conductivity of the first intermediate layer is different than a thermal energy conductivity of at least one of the first material or the second material; or an electrical energy conductivity of the first intermediate layer is different than an electrical conductivity of at least one of the first material or the second material.

In other features, the first intermediate layer is formed of a different material than the first one or more layers and the second one or more layers, such that: the thermal energy conductivity of the first intermediate layer is different than the thermal energy conductivity of at least one of the first material or the second material; and the electrical energy conductivity of the first intermediate layer is different than the electrical conductivity of at least one of the first material or the second material.

In other features, the first intermediate layer is formed of a different material than the first one or more layers and the second one or more layers, such that at least one of: the thermal energy conductivity of the first intermediate layer is different than the thermal energy conductivity of the first material and the second material; or the electrical energy conductivity of the first intermediate layer is different than the electrical conductivity of the first material and the second material.

In other features, a coefficient of thermal expansion of the first intermediate layer is different than a coefficient of thermal expansion of at least one of the first material or the second material.

In other features, the first intermediate layer includes an inner portion and an outer portion. The inner portion is formed of a different material than the first one or more layers and the second one or more layers. The outer portion is formed of the first material or the second material.

In other features, the substrate support further includes a metal layer disposed between the first intermediate layer and the second one or more layers. In other features, the metal layer is implemented as a metal screen or metal mesh. In other features, the second one or more layers are formed of the first material.

In other features, the first intermediate layer includes: an inner portion encased in a coating layer; and an outer portion surrounding the inner portion. In other features, the first intermediate layer includes a solid structure consolidated prior to consolidation of the first one or more layers, the second one or more layers and the first intermediate layer to form the monolithic anisotropic body.

In other features, the substrate support further includes a second intermediate layer disposed below the second one or more layers and formed of a different material than the first one or more layers and the second one or more layers, such that at least one of: a thermal energy conductivity of the second intermediate layer is different than the thermal energy conductivity of at least one of the first material or the second material; or an electrical energy conductivity of the second intermediate layer is different than the electrical conductivity of at least one of the first material or the second material.

In other features, the second intermediate layer includes an inner portion and an outer portion; the inner portion is formed of a different material than the first one or more layers and the second one or more layers; and the outer portion is formed of the first material or the second material.

In other features, the substrate support further includes: a first metal layer disposed between the first intermediate layer and the second one or more layers; and a second metal layer disposed between the second one or more layers and the second intermediate layer.

In other features, the first intermediate layer includes: a first inner portion encased in a first coating layer; and a first outer portion surrounding the first inner portion. The second intermediate layer includes: a second inner portion encased in a second coating layer; and a second outer portion surrounding the second inner portion.

In other features, the first intermediate layer includes a first solid structure and the second intermediate layer includes a second solid structure, which were consolidated prior to consolidation of the first one or more layers, the second one or more layers, the first intermediate layer and the second intermediate layer to form the monolithic anisotropic body. In other features, the monolithic anisotropic body includes a hollow interior area shaped similarly as the heating element and constraining the heating element. In other features, the monolithic anisotropic body includes fasteners for limiting movement of the heating element relative to the monolithic anisotropic body.

In other features, the first intermediate layer comprises at least one of a ring or a void. In other features, the first intermediate layer comprises a void filled with an insulating gas or a conductive fluid.

In other features, the monolithic anisotropic body includes vertically extending beams; and the beams are formed of a different material than the first one or more layers and the second one or more layers.

In other features, a substrate support is provided and includes a radio frequency electrode, a clamping electrode, a heating element, and a monolithic anisotropic body. The monolithic anisotropic body includes: a first one or more layers formed of a first material and including the radio frequency electrode and the clamping electrode; a second one or more layers formed of the first material or a second material and including the heating element; and an intermediate layer. The intermediate layer is formed of a different material than the first one or more layers and the second one or more layers, such that at least one of: a thermal energy conductivity of the intermediate layer is different than a thermal energy conductivity of at least one of the first material or the second material; or an electrical energy conductivity of the intermediate layer is different than an electrical conductivity of at least one of the first material or the second material. The second one or more layers are disposed between the first one or more layers and the intermediate layer.

In other features, the intermediate layer is formed of a different material than the first one or more layers and the second one or more layers, such that: the thermal energy conductivity of the intermediate layer is different than the thermal energy conductivity of at least one of the first material or the second material; and the electrical energy conductivity of the intermediate layer is different than the electrical conductivity of at least one of the first material or the second material.

In other features, the intermediate layer formed of a different material than the first one or more layers and the second one or more layers, such that at least one of: the thermal energy conductivity of the intermediate layer is different than the thermal energy conductivity of the first material and the second material; or the electrical energy conductivity of the intermediate layer is different than the electrical conductivity of the first material and the second material.

In other features, a coefficient of thermal expansion of the intermediate layer is different than a coefficient of thermal expansion of at least one of the first material or the second material. In other features, the intermediate layer includes an inner portion and an outer portion. The inner portion is formed of a different material than the first one or more layers and the second one or more layers. The outer portion is formed of the first material or the second material.

In other features, the substrate support further includes a metal layer disposed between the intermediate layer and the first one or more layers or the second one or more layers. In other features, the metal layer is implemented as a metal screen or metal mesh. In other features, the second one or more layers are formed of the material. In other features, the intermediate layer includes: an inner portion encased in a coating layer; and an outer portion surrounding the inner portion.

In other features, the intermediate layer includes a solid structure consolidated prior to consolidation of the first one or more layers, the second one or more layers and the intermediate layer to form the monolithic anisotropic body. In other features, the monolithic anisotropic body includes a hollow interior area shaped similarly as the heating element and constraining the heating element. In other features, the monolithic anisotropic body includes fasteners for limiting movement of the heating element relative to the monolithic anisotropic body. In other features, the intermediate layer includes at least one of a ring or a void. In other features, the intermediate layer includes a void filled with an insulating gas or a conductive fluid.

In other features, the monolithic anisotropic body includes vertically extending beams. The beams are formed of a different material than the first one or more layers and the second one or more layers.

In other features, a method of forming a substrate support is provided. The method includes: performing a first pre-form operation including collecting and arranging first material and a first one or more objects within a first die to create an initial pre-form; sintering the initial pre-form to provide a first initial internal structure; performing a second pre-form operation including collecting and arranging the first initial internal structure, second material, and a second one or more objects within a second die to create a final pre-form; and sintering the final pre-form to provide the substrate support. The first one or more objects and the second one or more objects include a heating element, a clamping electrode and a radio frequency electrode.

In other features, the method further includes applying pressure on the initial pre-form at least one of prior to or while sintering the initial pre-form. In other features, the method further includes refraining from applying pressure on the initial pre-form at least one of prior to or while sintering the initial pre-form. In other features, the method further includes applying pressure on the final pre-form at least one of prior to or while sintering the final pre-form. In other features, the method further includes refraining from applying pressure on the final pre-form at least one of prior to or while sintering the final pre-form.

In other features, the method further includes forming internal structures including the initial internal structure. The second pre-form operation includes arranging the internal structures in the second die.

In other features, the method further includes: collecting and arranging the first initial internal structure and at least one of third material or a third one or more objects in a third die to form an intermediate pre-form; and sintering the intermediate pre-form to form an intermediate internal structure. The second pre-form operation includes arranging the intermediate internal structure in the second die.

In other features, the method further includes machining the initial internal structure prior to performing the second pre-form operation and arranging the initial internal structure in the second die. In other features, the substrate support has a green sheet structure. In other features, the first pre-form operation includes forming a stack of layers.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a monolithic anisotropic substrate support having a stratified and/or lamellar structure in accordance with an example of the present disclosure;

FIG. 2 is a cross-sectional side view of an example of another monolithic anisotropic substrate support having a stratified and/or lamellar structure including metal layers in accordance with an example of the present disclosure;

FIG. 3. is a cross-sectional side view of an example of another monolithic anisotropic substrate support having a stratified and/or lamellar structure including coated layers in accordance with an example of the present disclosure;

FIG. 4 is a cross-sectional side view of an example of another monolithic anisotropic substrate support having a stratified and/or lamellar structure and providing constrained conformation in accordance with an example of the present disclosure;

FIG. 5 is a cross-sectional side view of an example of another monolithic anisotropic substrate support having a stratified and/or lamellar structure, providing constrained conformation and including fasteners in accordance with an example of the present disclosure;

FIG. 6 is a cross-sectional side view of an example of another monolithic anisotropic substrate support having a stratified and/or lamellar structure including rings in accordance with an example of the present disclosure;

FIG. 7 is a cross-sectional side view of an example of another monolithic anisotropic substrate support having a stratified and/or lamellar structure including beams in accordance with an example of the present disclosure;

FIG. 8 is a cross-sectional side view of an example of another monolithic anisotropic substrate support having a stratified and/or lamellar structure including plates and ceramic base material with different coefficients of thermal expansion in accordance with an example of the present disclosure;

FIG. 9 is a cross-sectional side view of an example of another monolithic anisotropic substrate support having a stratified and/or lamellar structure including voids in accordance with an example of the present disclosure;

FIG. 10 is an example of a substrate support manufacturing system including a substrate support controller in accordance with an example of the present disclosure; and

FIG. 11 illustrates a method of forming a substrate support in accordance with an example of the present disclosure.

In the drawings, reference numbers may be reused to identify similar and/or identical elements.

### DETAILED DESCRIPTION

Ceramic substrate supports formed by “hot pressing” suffer from a limited capacity. During hot pressing, material (e.g., powder) and other elements, such as electrodes and heater elements are disposed in a die to provide a pre-form. Temperature of the pre-form and pressure applied to the pre-form are increased to sinter the pre-form and provide a solid unitary object (or substrate support). During hot pressing, the material may creep and coalesce into a solid object. The resulting structure of a ceramic substrate support is constrained by the mass of the pre-form, which is limited by a capacity of the die, and density of the pre-form prior to sintering.

Ceramic electrostatic chucks with integrated heating elements suffer electrical energy losses from electronic conductivity between heating elements and clamping electrodes and RF electrodes (collectively “the electrodes”). A significant amount of clamping voltage and/or power is often dissipated due to shorting between the electrodes and the heating elements. The electrical losses limit a clamping voltage, which can be applied, and can require a power supply that provides a specified voltage and a higher output current level than would otherwise be needed.

Examples set forth herein include monolithic anisotropic substrate supports having multiple layers. Monolithic anisotropic substrates supports are formed to improve thermal energy spreading over traditional monolithic substrate supports. The examples include layers formed of different materials with different electrical and/or thermal conductivities. The layers are formed by sintering a pre-form, which may include electrical components, voids, channels, powder, structural elements (e.g., plates, rings, beams, voids, etc.), pre-sintered and/or pre-stressed objects, and/or other items. The pre-form may be sintered by hot pressing, as described above.

The examples provide improved thermal energy spreading throughout the substrate supports. The layers of the resultant substrate supports include different materials and/or structures to provide improved thermal energy spreading within given overall thicknesses of the substrate supports. The examples also prevent electrical dissipation between conductive elements in the substrate support.

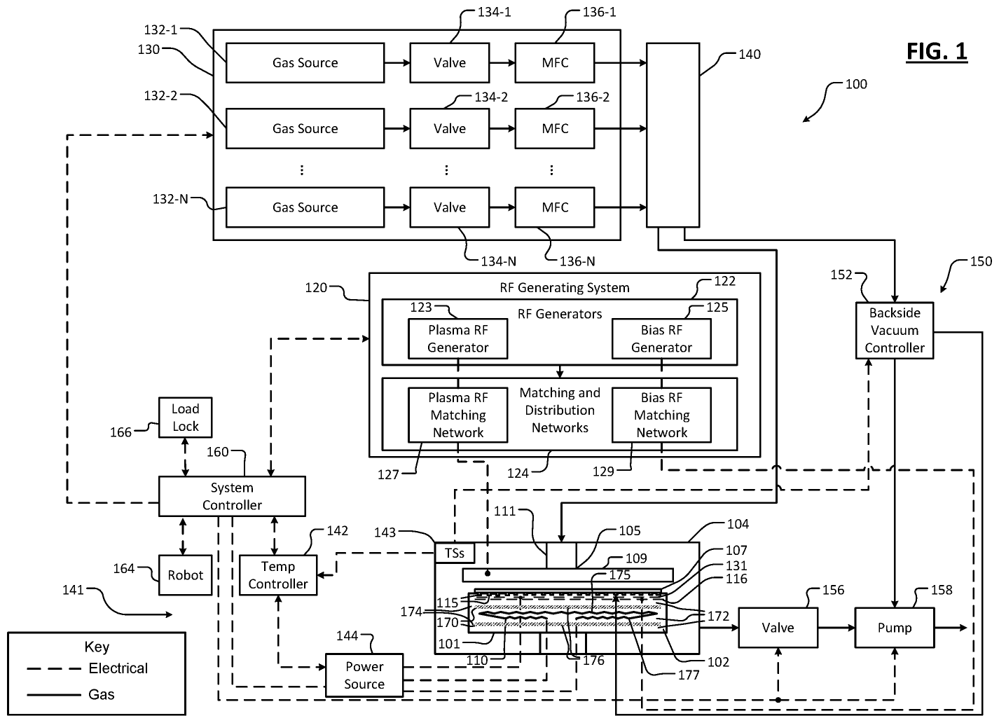

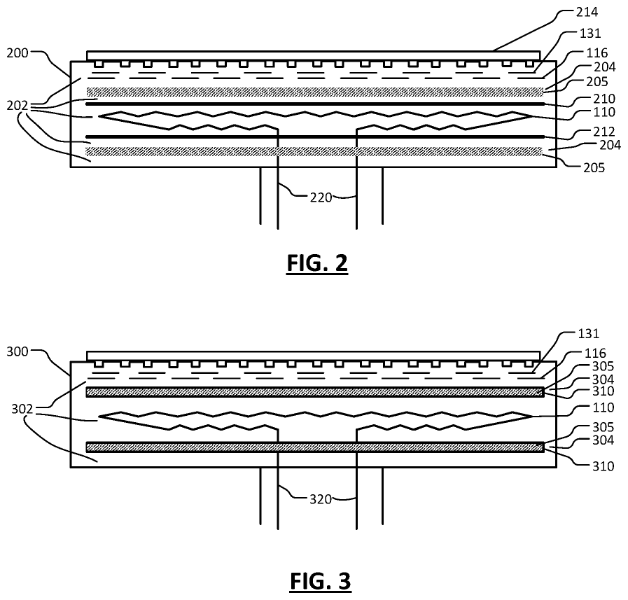

FIG. 1 shows a substrate processing system 100 that includes a substrate support, shown as an ESC 101. The ESC 101 may be configured the same or similarly as any of the substrate supports disclosed herein including that shown in FIGS. 2-9. Although FIG. 1 shows a capacitive coupled plasma (CCP) system, the embodiments disclosed herein are applicable to transformer coupled plasma (TCP) systems, inductively coupled plasma (ICP) systems and/or other systems and plasma sources that include a monolithic substrate support. The embodiments are applicable to plasma enhanced chemical vapor deposition (PECVD) processes, chemically enhanced plasma vapor deposition (CEPVD) processes, atomic layer deposition (ALD) processes, and/or other processes in which substrate temperatures are greater than or equal to 450° C. The ESC 101 includes a monolithic anisotropic body 102. The body 102 may be formed of different materials and/or different ceramic compositions. The body 102 may include, for example, aluminum nitride (AlN₃), aluminum oxide (Al₂O₃), and/or aluminum oxynitride (AlON).

The substrate processing system 100 includes a processing chamber 104. The ESC 101 is enclosed within the processing chamber 104. The processing chamber 104 also encloses other components, such as an upper electrode 105, and contains RF plasma. During operation, a substrate 107 is arranged on and electrostatically clamped to the ESC 101. For example only, the upper electrode 105 may include a showerhead 109 that introduces and distributes gases. The showerhead 109 may include a stem portion 111 including one end connected to a top surface of the processing chamber 104. The showerhead 109 is generally cylindrical and extends radially outward from an opposite end of the stem portion 111 at a location that is spaced from the top surface of the processing chamber 104. A substrate-facing surface of the showerhead 109 includes holes through which process or purge gas flows. Alternately, the upper electrode 105 may include a conducting plate and the gases may be introduced in another manner.

The ESC 101 may include temperature control elements (TCEs) also referred to as heating elements. As an example, FIG. 1 shows the ESC 101 including a heating element 110. The heating element 110 receives power and heats the ESC 101. In an embodiment, the ESC 101 includes one or more gas channels 115 for flowing backside gas to a backside of the substrate 107.

An RF generating system 120 generates and outputs RF voltages to the upper electrode 105 and one or more lower electrodes 116 in the ESC 101. One of the upper electrode 105 and the ESC 101 may be DC grounded, AC grounded or at a floating potential. For example only, the RF generating system 120 may include one or more RF generators 122 (e.g., a capacitive coupled plasma RF power generator, a bias RF power generator, and/or other RF power generator) that generate RF voltages, which are fed by one or more matching and distribution networks 124 to the upper electrode 105 and/or the ESC 101. An electrode that receives an RF signal, an RF voltage and/or RF power is referred to as a RF electrode. As an example, a plasma RF generator 123, a bias RF generator 125, a plasma RF matching network 127 and a bias RF matching network 129 are shown. The plasma RF generator 123 may be a high-power RF generator producing, for example, 6-10 kilo-watts (kW) of power or more. The bias RF matching network supplies power to RF electrodes, such as RF electrodes 116.

A gas delivery system 130 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. Vaporized precursor may also be used. The gas sources 132 are connected by valves 134-1, 134-2, . . . , and 134-N (collectively valves 134) and mass flow controllers 136-1, 136-2, . . . and 136-N (collectively mass flow controllers 136) to a manifold 140. An output of the manifold 140 is fed to the processing chamber 104. For example only, the output of the manifold 140 is fed to the showerhead 109.

The substrate processing system 100 further includes a heating system 141 that includes a temperature controller 142, which may be connected to the heating element 110. The temperature controller 142 controls a power source 144, which supplies power to the heating element 110. Although shown separately from a system controller 160, the temperature controller 142 may be implemented as part of the system controller 160. The ESC 101 may include multiple temperature controlled zones, where each of the zones includes temperature sensors and heating elements. The temperature controller 142 may monitor temperatures as indicated by the temperature sensors and adjust current, voltage and/or power to the heating elements to adjust the temperatures to target temperatures. The power source 144 may also provide power, including a high voltage, to clamping electrodes 131 to electrostatically clamp the substrate 107 to the ESC 101. Clamping electrodes receive power to electrostatically clamp down the substrate 107 to the ESC 101. The power source 144 may be controlled by the system controller 160.

The substrate processing system 100 further includes a cooling system 150 that includes a backside vacuum controller 152. The backside vacuum controller 152 may receive gas from the manifold 140 and supply the gas to the channels 115 and/or to a pump 158. This improves transfer of thermal energy between the substrate support 101 and the substrate 107. The backside gas may also be provided to improve substrate peripheral edge purging and vacuum tracking of a location of the substrate. The channels 115 may be fed by one or more injection ports. In one embodiment, multiple injection ports are included for improved cooling. As an example, the backside gas may include helium.

The temperature controller 142 may control operation and thus temperatures of heating elements and, as a result, temperatures of a substrate (e.g., the substrate 107). The temperature controller 142 controls current supplied to the heating elements based on detected parameters from temperature sensors 143 within the processing chamber 104. The backside vacuum controller 152 controls flow rate of backside gas (e.g., helium) to the gas channels 115 for cooling the substrate 107 by controlling flow from one or more of the gas sources 132 to the gas channels 115. The backside vacuum controller 152 controls pressure and flow rates of gas supplied to channels 115 based on detected parameters from the temperature sensors 143. In one embodiment, the temperature controller 142 and the backside vacuum controller 152 are implemented as a combined single controller.

The temperature sensors 143 may include resistive temperature devices, thermocouples, digital temperature sensors, and/or other suitable temperature sensors. During a deposition process, the substrate 107 may be heated in presence of high-power plasma. Flow of gas through the channels 115 may reduce temperatures of the substrate 107.

A valve 156 and the pump 158 may be used to evacuate reactants from the processing chamber 104. The system controller 160 may control components of the substrate processing system 100 including controlling supplied RF power levels, pressures and flow rates of supplied gases, RF matching, etc. The system controller 160 controls states of the valve 156 and the pump 158. A robot 164 may be used to deliver substrates onto, and remove substrates from, the ESC 101. For example, the robot 164 may transfer substrates between the ESC 101 and a load lock 166. The robot 164 may be controlled by the system controller 160. The system controller 160 may control operation of the load lock 166.

The valves, gas pumps, power sources, RF generators, etc. referred to herein may be referred to as actuators. The heating elements, gas channels, etc. referred to herein may be referred to as temperature adjusting elements.

In the example shown, the ECS 101 is a stratified and/or lamellar structure that includes the monolithic anisotropic body 102. The monolithic anisotropic body 102 is a solid monolithic structure able to be operated at high temperatures and does not need to be cooled to a temperature below an ambient temperature. The monolithic anisotropic body 102 may include five material layers as shown, where two intermediate material layers 170 are disposed between three material layers 172. The five layers 170, 172 are arranged in a stack. First (outer radial) portions 174 of the layers 170 may be integrally formed with the layers 172. In an embodiment, second (inner-disc-shaped) portions 176 of the layers 170 are formed of a different material than the layers 172, whereas the first portions 174 are formed of a same material as the layers 172. The first portions 174 may be ring-shaped and surround the second portions 176. The portions 176 may be used to (i) separate the heating element 110 from the electrodes 116, 131 in an area below the substrate 107, (ii) provide improved thermal energy spreading, and (iii) prevent power from being dissipated and/or shorted from the electrodes 116, 131 to the heating element 110. This provides more even heating across the substrate 107, prevents loss in power, and allows for use of a smaller power supply.

As an example, the layers 172, the first portions 174 and the second portions 176 may be formed of one or more ceramic compositions and may include, for example, aluminum nitride (AlN₃), aluminum oxide (Al₂O₃), and/or aluminum oxynitride (AlON). The layers 172, first portions 174 and second portions 176 may have different compositions and/or be formed of different materials. The second portions 176 may have better or worse thermal energy spreading characteristics than the layers 172 and the portions 174 within a given total thickness of the corresponding substrate support.

As an example, to increase thermal conductivity of the second portions 176 over the layers 172 and the first portions 174, the second portions 176 may include calcium oxide (CaO), yttrium oxide (Y₂O₃), cerium oxide (Ce₂O₃), yttrium fluoride (YF₃), and/or a combination thereof. Thermal conductivity may be increased by decreasing oxygen content during, for example, sintering of AlN₃. The oxygen content may be decreased using (i) Y₂O₃, and (ii) a nitrogen reducing atmosphere including carbon. As another example, when the layers 170, 172 are formed of AlN₃, the second portions 176 may be partially oxidized and/or one or more materials (e.g., aluminum oxide (Al₂O₃), silicon carbide (SiC), silicon mononitride (SiN), and/or aluminum carbide (Al₄C₃)) may be dissolved in the second portions 176 to decrease thermal conductivity of the second portions 176 relative to the layers 172 and the first portions 174.

The layers 172 and the portions 174, 176 may be formed to include additives having different properties to affect the thermal conductivity and/or electrical conductivity of the corresponding layer and/or portion. The layers 172 and portions 174, 176 may be formed of AlN₃ and the portions 176 may have different additives than the layers 170 and the portions 174. By forming the layers 172 and the portions 174, 176 of similar materials, this assures that the layers 170, 172 respond similarly to changes in temperature and power supplied to the heating element 110. As a result, there is less chance of substrate support cracking due to changes in the temperature and the power supplied to the heating element 110. The layers 172 and portions 174, 176 may be formed to include (i) a glass additive for transient liquid phase sintering, (ii) magnesium oxide (MgO), and/or (iii) other additive.

In one embodiment, the portions 176 are formed prior to being included with the material to form the layers 172 and the portions 174. The material used to form the portions 176 is sintered to form disc-shaped plates, which are than included along with other material to form the layers 172 and the portions 174 as a pre-form. The pre-form is then sintered to form a final solid object.

In the example shown, the electrodes 116, 131 are disposed in the uppermost one of the layers 172. The heating element 110 is disposed in the second (or middle) one of the layers 172. In an embodiment, the heating element 110 is circular-shaped and/or disc-shaped. The heating element 110 may include a top electrode 175 and a bottom electrode 177 that are connected to each other along circumferential edges of the electrodes 175, 177. In an embodiment, the top electrode 175 and the bottom electrode 177 are circular-shaped, disc-shaped, and/or perforated. Although a single heating element 110 is shown, any number of heating elements may be included in the ESC 101. The heating elements may have different sizes, shapes and provide corresponding heating patterns and be allocated to respective heating zones of the ESC 101. One of the layers 170 is disposed between the electrodes 116, 131 and the heating element 110. The other one of the layers 170 is disposed below the heating element 110.

The layers 172, 174 may be formed of highly thermal energy conductive material. In an embodiment, the portions 176 have lower thermal energy conductivity than the layers 172 and the portions 174. As yet another example, the portions 176 may be formed of a material that has higher electrical resistance than surrounding ceramic material. This is implemented to: prevent shorting between electrodes and heater elements; prevent loss in power and save energy; and allow for use of smaller power supplies.

In another embodiment, the portions 176 are formed of pure AlN₃, perform as separation layers and are more resistive than surrounding less pure AlN₃ layers. The surrounding AlN₃ layers at least partially include different materials than the portions 176. In another embodiment, the portions 176 are formed of AlON, which is more resistive than surrounding material of the layers 172 and portions 174, which are formed of AlN₃. In the stated embodiment, AlN₃ has less thermal energy conductivity than the portions 176, which are formed of AlON. AlON has a different coefficient of thermal expansion than AlN₃.

The portions 176 may be sintered to a fraction of theoretical density to improve adhesion during hot pressing. The sintered portions 176 may be machined to a predetermined geometric shape and then provided with a surface treatment and/or coating for improved adhesion to surrounding material (e.g., material used to form the layers 172 and the portions 174). A pre-form may be created to include (i) the machined portions 176, (ii) other internal structures (RF electrodes, clamping electrodes, heating elements, etc.), and (iii) material (e.g., powder) to form the layers 172 and portions 174. The machined portions and internal structures may be embedded in compressed powder (material used to form the layers 172 and the portions 174). The compressed powder may have a higher thermal energy conductivity than the portions 176.

In one embodiment, thermal energy conductivity of the layers 172 from a center to a circumferential edge is the same. For the same embodiment, thermal energy conductivity of the portions 176 is the same from center to a circumferential edge. The thermal energy conductivity of the layers 172 is however different than the thermal energy conductivity of the portions 176.

As described, the pre-form created to form the resulting substrate support may be formed of multiple layers. This may be accomplished by providing a green sheet structure that is hot pressed, such that powder and any internal plates and/or other structural elements bond together as the structure sinters to a value at or near the theoretical density of the corresponding ceramic material. The theoretical density being a parameter indicative of and/or used to estimate porosity of the ceramic material after sintering. Powder may be tightly or loosely packed when forming the green sheet structure. Portions of the green sheet structure may be consolidated (e.g., pre-sintered, joined, welded, and/or otherwise united to form a single solid structure) prior to a final consolidation of the whole green sheet structure.

Sintering may be performed any number of times to assure proper placement of internal components. Ceramic plates, wires, electrodes, and/or other structural elements and circuit components may be added along with, for example, ceramic powder during each sintering phase performed. By having some layers and/or structural elements sintered prior to creating a pre-form of a substrate support, allows a die of a hot press to be more tightly packed. This also allows for more accurate placement of circuit components and a minimal amount of movement during a final sintering phase. An example of the above-described method is described below with respect to FIG. 11.

In one embodiment, the upper one of the portions 176 has a low electrical conductivity and the lower one of the portions 176 has a high electrical conductivity.

Although the ESCs of FIGS. 1-9 are each shown as having certain features and not other features, each of the ESCs may be modified to include any of the features disclosed herein and in FIGS. 1-9.

FIG. 2 shows a monolithic anisotropic substrate support 200 having a stratified and/or lamellar structure including layers 202, which may be similar to layers 172 of FIG. 1. The monolithic anisotropic substrate support 200 further includes layers 204 having inner portions 205, which may be similar to layers 170 of FIG. 1. The inner portions 205 are formed of and/or include different materials than the layers 302 and/or portions of the layers 204 surrounding the portions 205. The monolithic anisotropic substrate support 200 may also include the electrodes 116, 131 and the heating element 110 and/or other electrodes and heating elements. The monolithic anisotropic substrate support 200 further includes metal layers 210, 212. The metal layers 210, 212 in effect provide a Faraday cage to prevent backside discharge between the electrodes 116, 131 and the substrate 214. The metal layer 210 may electrically shield a top surface of the substrate support 200 from the heating element 110. The metal layer 212 may electrically shield a bottom surface of the substrate support 200 from the heating element 110.

Although the metal layers 210, 212 are shown in particular locations relative to the other layers 202, 204 and the heating element 110, the metal layers 210, 212 may be in other locations. The metal layers 210, 212 may be incorporated to aid in spreading heat. The metal layers 210, 212 may have a relatively uniform temperature while at the same time diffuse thermal energy. In one embodiment, the layers 210, 212 are formed of a material having a high thermal conductivity. The layers 210, 212 aid in preventing hot spots from occurring in the substrate support 200 and a substrate 214 disposed on the substrate support 200.

In one embodiment, the metal layers 210, 212 are implemented as metal screens or meshes that are disc-shaped. The metal layers 210, 212 may be formed using metal screen printing and/or include the stacking of multiple metallic layers resulting in a composite structure. The metal layers 210, 212 may be implemented as perforated plates. In the example shown, the metal layer 210 is disposed between the heating element 110 and the upper one of the layers 204. The metal layer 212 is disposed between the heating element and the lower one of the layers 204. Portions of the substrate support 200 surrounding the layers 210, 212 may be formed of a same or similar material as the layers 202 and/or the portions of the substrate support 200 surrounding the layers 204. The bottom one of the layers 204 and the metal layer 212 may include openings for passage of conductors 220 providing current to and receiving current from the heating element 110.

FIG. 3. shows a monolithic anisotropic substrate support 300 having a stratified and/or lamellar structure including layers 302, which may be similar to layers 172 of FIG. 1. The monolithic anisotropic substrate support 300 further includes layers 304, which may be similar to layers 170 of FIG. 1. Inner portions 305 of the layers 304 are formed of and/or include different materials than the layers 302 and/or portions of the layers 304 surrounding the portions 305. The monolithic anisotropic substrate support 300 may also include the electrodes 116, 131 and the heating element 110 and/or other electrodes and heating elements. In the example shown, the inner portions 305 of the layers 304 are coated in an additive and/or are modified with a chemical surface treatment that locally alters thermal conductivity of the surrounding (or coating) material. The portions 305 have an outer coating layer 310. The portions 305 may be disposed within the outer coating layer 310. The outer coating layers 310 may respectively envelope the portions 305.

In an embodiment, the portions 305 are implemented as plates formed of a material having high thermal energy conductivity. The plates may be formed of a ceramic material. In another embodiment, the plates have a solid material selected to react with or dissolve into surrounding ceramic material during sintering. The coating layers 310 are formed of a material chosen to increase or decrease the concentration of atoms in a solid solution within the ceramic, thereby modifying local thermal conductivity of the plates to provide a layered structure. In one embodiment, coatings on the portions 305 react with surrounding ceramic during sintering, which forms reaction layers with distinct properties. This triples a number of layers per plate. The bottom one of the portions 305 and corresponding outer coating layer 310 may include openings for passage of conductors 320 providing current to and receiving current from the heating element 110.

In addition and/or as an alternative to the portions 205, 305 of FIGS. 2-3, a sheet of solid material may be used to constrain relative position of substrate support components (e.g., RF electrodes, clamping electrodes, heating elements, etc.) to improve repeatable placement of the components during manufacturing of the corresponding substrate support. The sheets may be structured similarly as the portions 205, 305. In one embodiment, the sheets extend to perimeters of the substrate supports, unlike the shown examples of portions 205, 305. The substrate supports disclosed herein may have any number of layers and sheets of solid material.

In FIGS. 2-3, the pre-sintered plates 205, 305, may be disposed in close proximity to planes of heater circuitry, where each of the planes includes portions of one or more heating elements. This close proximity may be provided to reduce influence of initial density variations on final locations of the heating elements post sintering.

One or more layers of ceramic material with increased electrical resistivity at service temperature (e.g., 111 ohm meter (Ωm) at 650° C.) may be disposed between the clamping electrodes 131 and the heating element 110. The service temperature may be greater than the surrounding ceramic bulk material (e.g., 19 Ωm at 650° C.). As an example, one or more of the plates 205, 305 may be formed of the ceramic material having the increased electrical resistivity. This prevents electrical losses from the clamping electrodes 131 and/or RF electrodes 116 to the heating element 110.

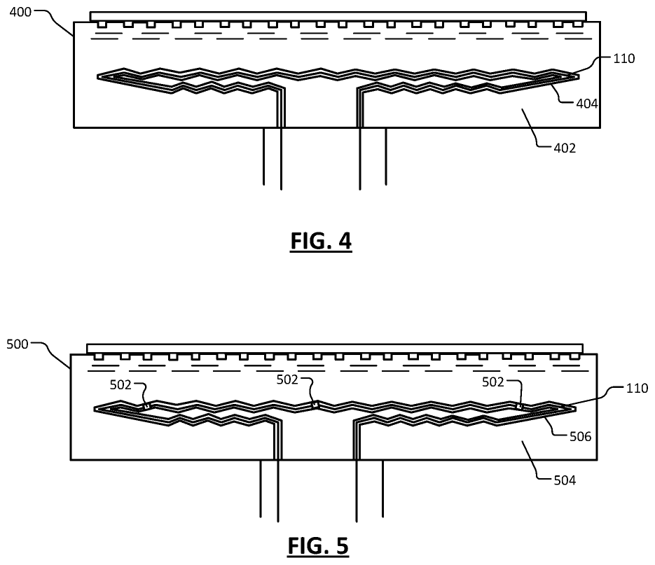

FIG. 4 shows a monolithic anisotropic substrate support 400 having a stratified and/or lamellar structure and providing constrained conformation. The substrate support 400 includes a base 402 that is shaped to receive a heating element 110. The base 402 may be formed of ceramic material and include grooves and/or other indentations, channels, recessed areas, etc. that are shaped to match and/or hold one or more heating elements. In the example shown, the ceramic plate 402 has a hollow interior area 404 that is shaped to match a shape of the heating element 110. The heating element 110 is disposed in the hollow interior area 404 and is constrained by the base 402. In an embodiment, the base 402 is shaped to receive the heating element 110 in a designed conformation of the heating element. In another embodiment, the heating element is affixed to the ceramic base via an adhesive material.

FIG. 5 shows a monolithic anisotropic substrate support 500 having a stratified and/or lamellar structure, providing constrained conformation and including fasteners 502. Any number of fasteners may be included. The substrate support 500 is similar to the substrate support 400 of FIG. 4, except that the substrate support 500 includes the fasteners 502. The fasteners 502 may be implemented as tabs as shown, or may be implemented as hooks, blocks, guides, etc. which limit movement of at least a portion of the heating element 110 and/or other heating elements relative to the base 504. The base 504 may be formed of ceramic and has a hollow interior area 506 that is shaped to match the shape of the heating element 110. The fasteners 502 may have different shapes and sizes. Different types of fasteners may be included and the fasteners may prevent and/or limit movement of at least respective portions of the heating element 110 relative to the base 504.

In another embodiment, the heating element 110 is affixed to the base 504 via an adhesive. In another embodiment, a sinterable pre-form of material may be: affixed to the base 504 prior to placement in a die; used as a fastener; and shaped to constrain a location of at least a portion of the heating element 110.

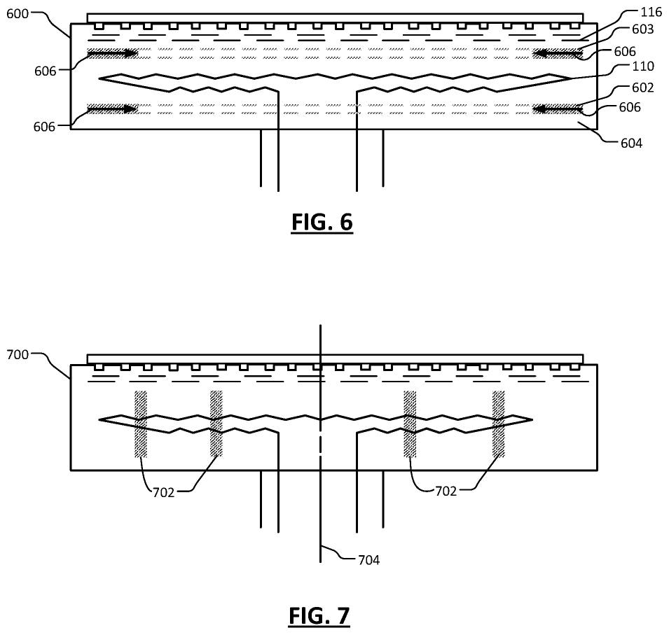

To minimize vulnerability to thermal stress, structural elements (e.g., plates, rings, or beams) may be included in a substrate support. Examples including rings, beams and plates are shown respectively in FIGS. 6-8. The structural elements may be placed to counteract tensile stresses in selected portions of the substrate support, such as at or near a top surface of the substrate support. The structural elements may be included to cause tension and/or internal tensile stress. For example, the structural elements may have greater thermal expansion than the surrounding material and as a result cause tension between the structural elements and the surrounding material when the structural elements expand. Also, when the corresponding substrate support cools, the structural elements may shrink more than the surrounding material and cause the surrounding material to be compressed. In one embodiment, the structural elements have the same or similar thermal energy conductivity properties as the surrounding material, but have different coefficients of expansion than the surrounding material.

FIG. 6 shows a monolithic anisotropic substrate support 600 having a stratified and/or lamellar structure including rings 602, 603. The thicknesses, inner and outer diameters, and/or material makeup of the rings 602, 603 may be set to provide the appropriate amount of local thermal conductance and/or tensile stress. In the example shown, the rings 602, 603 may extend horizontally and/or in parallel with a bottom surface of the substrate support 600. The first ring 602 is disposed between a bottom of a base 604 of the substrate support 600 and the heating element 110. The second ring 603 is disposed between the heating element 110 and the RF electrodes 116. In an embodiment, the rings 602, 603 are formed of ceramic material having a coefficient of thermal expansion greater than the coefficient of thermal expansion of the base 604. The base 604 may be formed of a ceramic material having a different composition than the ceramic material of the rings 602, 603. The rings 602, 603 may be included to apply internal tensile stress, which may occur due to, for example, radially inward thermal contraction of the rings 602, 603. This contraction is illustrated by the arrow 606.

FIG. 7 shows a monolithic anisotropic substrate support 700 having a stratified and/or lamellar structure including beams 702. Any number of beams may be included. The lengths, width, horizontal cross-sectional areas and shapes, and/or material makeup of the beams 702 may be set to provide the appropriate amount of local thermal conductance and/or tensile stress. The beams 702 may extend vertically and/or in parallel with each other. In one embodiment, the beams 702 are equidistantly placed relative to each other and/or from a vertical centerline 704 of the substrate support 700. The beams 702 may be symmetrically placed relative to one or more vertically extending planes passing through the centerline 704.

One or more structural members may be added, where each of the structural elements has a greater coefficient of thermal expansion (CTE) than the bulk ceramic material of the corresponding substrate support. The structural elements may include plates, rings, beams, etc. as shown in the provided figures. Tensile stresses may be induced due to differences in (i) a fabrication temperature at which the structural members assume corresponding final shapes, and (ii) a service temperature of the bulk ceramic material.

In an embodiment and after sintering, the resulting structure created to include the structural members is heat-treated at a temperature at which the structural members (e.g., structural members having high CTE values) deform at a greater rate than the surrounding material. This may be referred to as creep deformation, which relieves a controlled amount of stress.

In another embodiment, different parts of a substrate support may be formed to experience different rates of creep. This may be done by heat treating, doping, and/or performing some other treatment on selected portions of the substrate support in order to control a final overall stress profile of the substrate support.

In yet another embodiment, the structural elements may be formed of ceramic material and coated in an additive or modified via a chemical surface treatment, which locally alters the CTE of the surrounding materials of the corresponding substrate support. In another embodiment, a solid material, having a selected size and shape, is added to the bulk ceramic material in one or more preselected locations and locally reacts with and/or dissolves into the bulk ceramic material during sintering. This modifies, in each of the locations, the local CTE and forms a structural member in the bulk ceramic material (or body) of the substrate support.

In an embodiment, ceramic plates to be included in a pre-form of a substrate support are formed and sintered with no applied pressure and then added with other material to form the pre-form. This may be done to reduce height of the pre-form for a given final volume and allows for a greater number of pre-forms to be fit into an internal volume of a die.

Pre-stressed ceramic bodies that are resistant to fractures may be formed and combined with other materials and internal components to form a pre-form as described above. This allows materials for structural elements of a substrate support to be consolidated (e.g., sintered, welded, joined, and/or made into a single solid body) prior to forming a pre-form of a substrate support including the consolidated structural elements. This may be done to provide greater control of placement of internal structures of a substrate support during sintering and to increase throughput of systems used to manufacture substrate supports. This is different than traditional hot pressed ceramic substrate supports, which are formed by sintering all the ceramic powder used to form the corresponding structure at the same time.

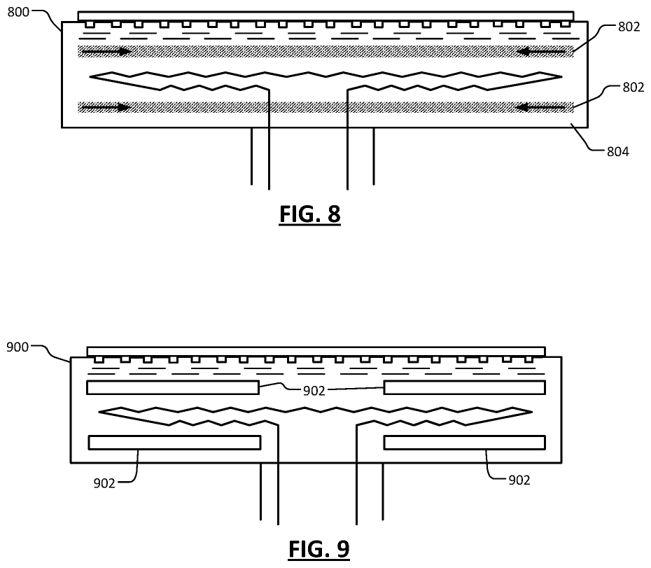

FIG. 8 shows a monolithic anisotropic substrate support 800 having a stratified and/or lamellar structure including plates 802 and ceramic base material 804 with different coefficients of thermal expansion. The substrate support 800 may include metal layers, screens, rings, beams, coating layers, voids, and/or other objects having different material compositions with distinct properties, such as distinct coefficients of thermal expansion, electrical conductivity, and/or electrical resistivity, as described with respect to FIGS. 2-7 and 9. The example of FIG. 8 includes the plates 802, but may include any of the other stated items. The thicknesses, diameters, and/or material makeup of the plates 802 may be set to provide the appropriate amount of thermal conductance, electrical conductivity, electrical resistivity and/or local tensile stress.

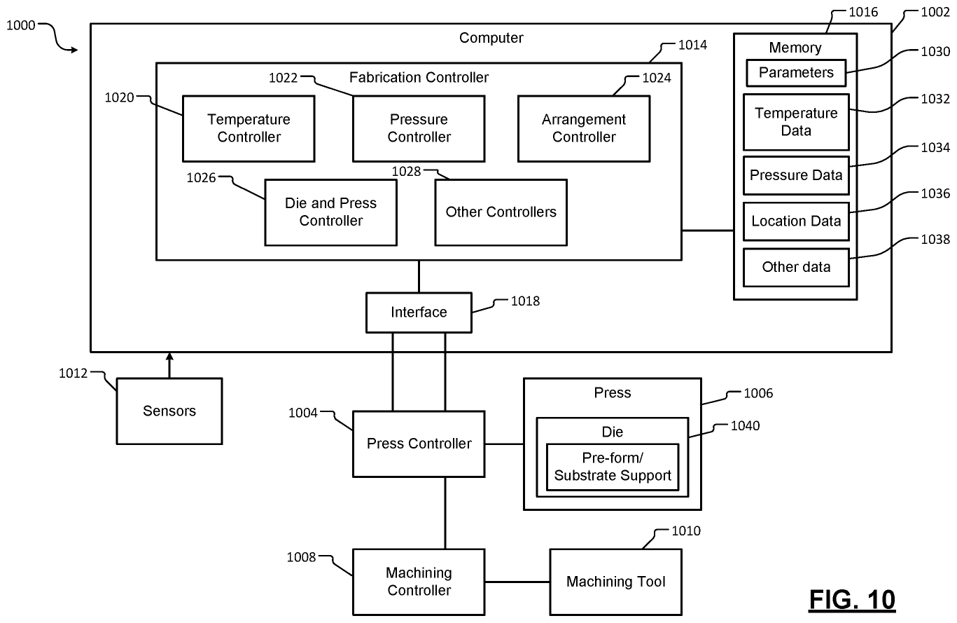

FIG. 9 shows a monolithic anisotropic substrate support 900 having a stratified and/or lamellar structure and may include internal voids and/or channels (example voids 902 are shown) on specific layers. The internal voids and the channels are disposed to modify thermal conductance. The voids 902 may be in distinct isolated locations in the substrate support 900. The channels may be referred to as voids. As a couple of examples, the channels may be ring-shaped and/or spiral shaped. The voids and channels may be void of any gas, liquid and/or material. In one embodiment, one or more of the voids and channels are filled with low-pressure insulating gas, such as sulfur hexafluoride (SF₆), argon (Ar), krypton (Kr), etc. for reduced conductance. In another embodiment, one or more of the voids and channels are filled with a conductive fluid. The conductive fluid may include high-pressured helium (He) or a metal, such as gallium (Ga), indium (In), and/or tin (Sn). The conductive fluid may be included to increase heat transfer (forced convection, natural convection, etc.). The sizes, shapes, thicknesses, diameters, and/or internal materials in the voids and channels may be set to provide the appropriate amount of thermal conductance, electrical conductivity, electrical resistivity and/or local tensile stress.

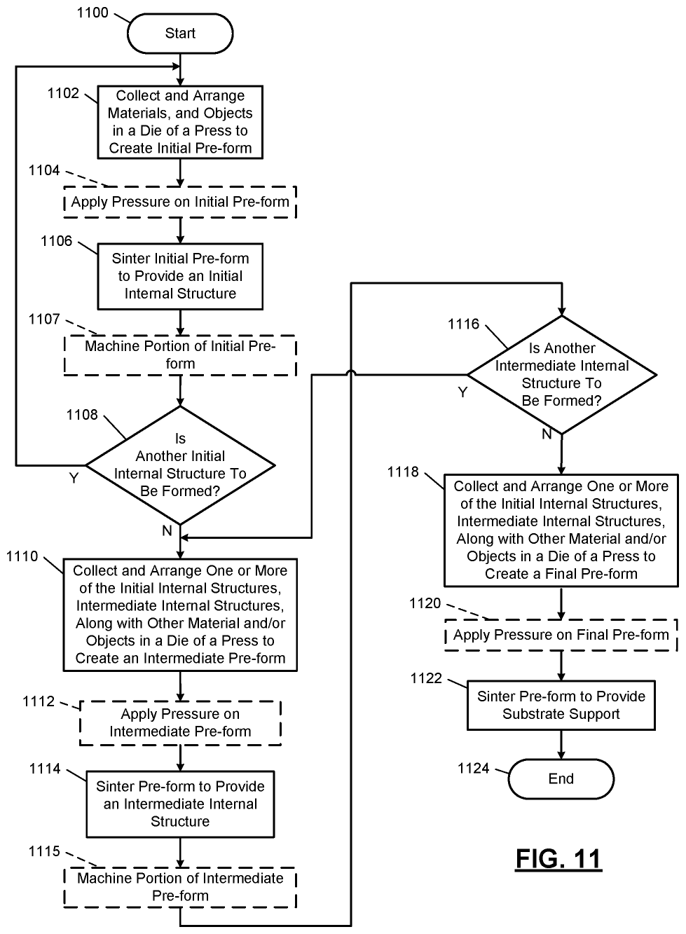

FIG. 10 shows a substrate support manufacturing system 1000 that includes a computer 1002, a press controller 1004 controlling one or more presses (a single press 1006 is shown), a machining controller 1008 controlling one or more machining tools (one machining tool 1010 is shown), and sensors 1012. The computer 1002 may include a fabrication controller 1014, a memory 1016 and an interface 1018.

The fabrication controller 1014 may include a temperature controller 1020, a pressure controller 1022, an arrangement controller 1024, a die and press controller 1026, and/or other controllers 1028. Some of the operations of the controllers 1014, 1020, 1022, 1024, 1026 and 1028 are described below with respect to the method of FIG. 11.

The memory 1016 may store, for example, parameters 1030, temperature data 1032, pressure data 1034, location data 1036, and/or other data 1038. The parameters 1030, and data 1032, 1034, 1036 and 1038 may correspond to models of substrate supports and/or be stored as part of tables and include historical, predetermined, estimated, simulated and/or measured values. The parameters 1030 may include parameters detected by sensors 1012, which may include parameters used, estimated, measured and/or determined during the method of FIG. 11. The sensors 1012 may be located on the press 1006, the machining tool 1010, and/or elsewhere. The sensors 1012 may include temperature sensors, pressure sensors, position sensors, etc.

The temperature data 1032 may include temperatures of, for example, a die 1040 located in the press 1006. The pressure data may include pressures applied to the die 1040. Although a single press and a single die are shown, the press controller may be connected to and/or control multiple presses and dies. The die may include an initial pre-form, an intermediate pre-form, a final preform and/or a resulting substrate support. The stated pre-forms are further described below with respect to FIG. 11.

The machining tool 1010 may include a computer numerical control (CNC) milling machine, a knurling machine, a molding machine, a casting machine, a three-dimensional (3D) printer, and/or other machines and/or devices suitable for fabricating and/or modifying objects and/or internal structures to be included in a pre-form. The machining controller 1008 may receive control signals, parameters and/or data from the controllers 1014, 1020, 1022, 1024, 1026, 1028 via an interface 1018. The controllers 1014, 1020, 1022, 1024, 1026, 1028 control operation of the press controller 1004 and the machining controller 1008 to fabricate a substrate support.

The substrate supports disclosed herein may be formed using numerous methods, an example method is illustrated in FIG. 11, which may include some of the manufacturing implementations described above. In FIG. 11, a method of forming a substrate support is shown. Although the following operations are primarily described with respect to the implementations of FIGS. 1-10, the operations may be easily modified to apply to other implementations of the present disclosure. The operations may be iteratively performed.

The method may begin at 1100. At 1102, material (e.g., ceramic powder and/or other material) and one or more objects (e.g., heating elements, electrodes, wires, plates, rings, beams, and/or other objects disclosed herein) are collected and arranged in a die of a press to form an initial pre-form.

At 1104, pressure may be applied to the initial pre-form. This may be referred to as a first or pre-consolidation operation. Operation 1104 may be performed prior to and/or during operation 1106. At 1106, the initial pre-form is sintered at a predetermined temperature. At 1107, a portion of the initial internal structure may be machined to remove material from and/or shape the initial internal structure.

At 1108, it is determined whether another internal structure is to be formed. Each iteration of the combination of operations 1102, 1104, and 1106 may include a different die and/or press.

At 1110, material (e.g., ceramic powder and/or other material), one or more initial internal structures, one or more intermediate internal structures, and/or one or more objects (e.g., heating elements, electrodes, wires, plates, rings, beams, and/or other objects disclosed herein) are collected and arranged in a die of a press to form an intermediate pre-form. The initial internal structures may be formed during iterations of operations 1102, 1104, 1106 and/or via other operations. The intermediate internal structures may be formed during iterations of operations 1110, 1112, 1114 and/or via other operations.

At 1112, pressure may be applied to the intermediate pre-form. This may be referred to as another pre-consolidation operation. Operation 1112 may be performed prior to and/or during operation 1114. At 1114, the intermediate pre-form is sintered at a predetermined temperature. At 1115, a portion of the intermediate internal structure may be machined to remove material from and/or shape the intermediate internal structure.

At 1116, it is determined whether another internal structure is to be formed. Each iteration of the combination of operations 1110, 1112, and 1114 may include a different die and/or press.

At 1118, material (e.g., ceramic powder and/or other material), one or more initial internal structures, one or more intermediate internal structures, and/or one or more objects (e.g., heating elements, electrodes, wires, plates, rings, beams, and/or other objects disclosed herein) are collected and arranged in a die of a press to form a final pre-form. The initial internal structures may be formed during iterations of operations 1102, 1104, 1106 and/or via other operations. The intermediate internal structures may be formed during iterations of operations 1110, 1112, 1114 and/or via other operations. At 1120, pressure may be applied to the final pre-form. This may be referred to as a final consolidation operation. Operation 1120 may be performed prior to and/or during operation 1122. At 1122, the final pre-form is sintered at a predetermined temperature. The method may end at 1124.

One or more of the above-described operations may include heat treating, doping, and/or performing some other treatment on a selected portion of one or more of the initial internal structures and intermediate internal structures in order to control a final overall stress profile of the substrate support.

During the above-described operations, structures are pre-formed by performing pre-consolidation operations followed by a final consolidation operation. Density (mass per unit area), porosity per unit area and/or number of cracks per unit area is different for each of the pre-formed structures than for remainders of the final product. The phrase “per unit area” refers to a preselected area or volume, based on which a substrate support or portion thereof is divided into equally sized units. For density, “per unit area” may refer to a volume. For porosity and number of cracks, “per unit area” may refer to a two-dimensional area or a volume. As an example, a first intermediate layer and a second intermediate layer may include respective solid structures that were pre-consolidated. The first and second intermediate layers may be disposed between other layers of the final product. The other layers and/or other portions of the intermediate layers subsequent to the final consolidation have different densities, porosities and/or numbers of cracks than the pre-formed structures. The pre-formed structures may have higher densities, less porosities and less cracks than the other layers and/or portions of the final product. As an example, the densities of the pre-formed structures may be 1% or more higher than the densities of the other layers and portions of the final product. As another example, the densities of the pre-formed structures may be 20% or more higher than the densities of the other layers and portions of the final product.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The above-described examples, allow an increased amount of ceramic material to be placed in a die prior to sintering and/or reduce a thickness of a bulk ceramic body needed to satisfy a predetermined thermal uniformity specification. Substrate support structures are arranged to account for improved heat spreading and place a wafer closer to heating elements. This is done without sacrificing thermal uniformity and allowing a thinner ceramic body to achieve a same or improved performance with less used raw material and a decreased amount of dies space and thus hot press capacity.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from multiple fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support comprising:
a radio frequency electrode;
a clamping electrode;
a heating element; and
a monolithic anisotropic body comprising
a first layer formed of a first material and disposed therein are the radio frequency electrode and the clamping electrode,
a second layer formed of the first material or a second material and disposed therein is the heating element, and
a first intermediate layer formed of a different material than the first layer and the second layer, such that at least one of
a thermal energy conductivity of the first intermediate layer is different than a thermal energy conductivity of at least one of the first material or the second material, or
an electrical energy conductivity of the first intermediate layer is different than an electrical conductivity of at least one of the first material or the second material,
either the first intermediate layer is disposed between the first layer and the second layer or the second layer is disposed between the first layer and the first intermediate layer.

2. The substrate support of claim 1, wherein the first intermediate layer is formed of a different material than the first layer and the second layer, such that:
the thermal energy conductivity of the first intermediate layer is different than the thermal energy conductivity of at least one of the first material or the second material; and
the electrical energy conductivity of the first intermediate layer is different than the electrical conductivity of at least one of the first material or the second material.

3. The substrate support of claim 1, wherein the first intermediate layer is formed of a different material than the first layer and the second layer, such that at least one of:
the thermal energy conductivity of the first intermediate layer is different than the thermal energy conductivity of the first material and the second material; or
the electrical energy conductivity of the first intermediate layer is different than the electrical conductivity of the first material and the second material.

4. The substrate support of claim 1, wherein a coefficient of thermal expansion of the first intermediate layer is different than a coefficient of thermal expansion of at least one of the first material or the second material.

5. The substrate support of claim 1, wherein:
the first intermediate layer includes an inner portion and an outer portion;
the inner portion is formed of a different material than the first layer and the second layer; and
the outer portion is formed of the first material or the second material.

6. The substrate support of claim 1, further comprising a metal layer disposed between the first intermediate layer and the second layer.

7. The substrate support of claim 6, wherein the metal layer is implemented as a metal screen or metal mesh.

8. The substrate support of claim 1, wherein the second layer is formed of the first material.

9. The substrate support of claim 1, wherein the first intermediate layer comprises:
an inner portion encased in a coating layer; and
an outer portion surrounding the inner portion.

10. The substrate support of claim 1, wherein the first intermediate layer includes a solid structure having at least one of a different density, porosity per unit area or number of cracks per unit area than the first layer, the second layer and the first intermediate layer of the monolithic anisotropic body.

11. The substrate support of claim 1, further comprising a second intermediate layer disposed below the second layer and formed of a different material than the first layer and the second layer, such that at least one of:
a thermal energy conductivity of the second intermediate layer is different than the thermal energy conductivity of at least one of the first material or the second material; or
an electrical energy conductivity of the second intermediate layer is different than the electrical conductivity of at least one of the first material or the second material.

12. The substrate support of claim 11, wherein:
the second intermediate layer includes an inner portion and an outer portion;
the inner portion is formed of a different material than the first layer and the second layer; and
the outer portion is formed of the first material or the second material.

13. The substrate support of claim 11, further comprising:
a first metal layer disposed between the first intermediate layer and the second layer; and
a second metal layer disposed between the second layers and the second intermediate layer.

14. The substrate support of claim 11, wherein:
the first intermediate layer comprises
a first inner portion encased in a first coating layer, and
a first outer portion surrounding the first inner portion; and
the second intermediate layer comprises
a second inner portion encased in a second coating layer, and
a second outer portion surrounding the second inner portion.

15. The substrate support of claim 11, wherein:
the first intermediate layer includes a first solid structure and the second intermediate layer includes a second solid structure; and
the first solid structure and the second solid structure have at least one of a different density, porosity per unit area or number of cracks per unit area than the first layer, the second layer, a remainder of the first intermediate layer and a remainder of the second intermediate layer of the monolithic anisotropic body.

16. The substrate support of claim 1, wherein the monolithic anisotropic body comprises a hollow interior area shaped similarly as the heating element and constraining the heating element.

17. The substrate support of claim 1, wherein the monolithic anisotropic body includes fasteners for limiting movement of the heating element relative to the monolithic anisotropic body.

18. The substrate support of claim 1, wherein the first intermediate layer comprises at least one of a ring or a void.

19. The substrate support of claim 1, wherein the first intermediate layer comprises a void filled with an insulating gas or a conductive fluid.

20. The substrate support of claim 1, wherein:
the monolithic anisotropic body includes vertically extending beams; and
the beams are formed of a different material than the first layer and the second layer.

21. A method of forming a substrate support, the method comprising:
arranging first material and a first object within a first die to create an initial pre-form;
sintering the initial pre-form to provide a first initial internal structure;
arranging the first initial internal structure, second material, and a second object within a second die to create a final pre-form; and
sintering the final pre-form to provide the substrate support,
wherein the first object and the second object include a heating element, a clamping electrode and a radio frequency electrode.

22. The method of claim 21, further comprising applying pressure on the initial pre-form at least one of prior to or while sintering the initial pre-form.

23. The method of claim 21, further comprising refraining from applying pressure on the initial pre-form at least one of prior to or while sintering the initial pre-form.

24. The method of claim 21, further comprising applying pressure on the final pre-form at least one of prior to or while sintering the final pre-form.

25. The method of claim 21, further comprising refraining from applying pressure on the final pre-form at least one of prior to or while sintering the final pre-form.

26. The method of claim 21, further comprising forming a plurality of internal structures including the initial internal structure,
wherein the creating of the final pre-form includes arranging the plurality of internal structures in the second die.

27. The method of claim 21, further comprising:
collecting and arranging the first initial internal structure and at least one of third material or a third object in a third die to form an intermediate pre-form; and
sintering the intermediate pre-form to form an intermediate internal structure,
wherein the creating of the final pre-form includes arranging the intermediate internal structure in the second die.

28. The method of claim 21, further comprising machining the initial internal structure prior to creating the final pre-form and arranging the initial internal structure in the second die.

29. The method of claim 21, wherein the substrate support has a green sheet structure.

30. The method of claim 21, wherein the creating of the initial preform includes forming a stack of a plurality of layers.
